(19) United States
(12) Patent Application Publication
(10) Pub. No.: US 2005/0101045 A1
(43) Pub. Date: May 12, 2005

(54) Sealing openings in micro-electromechanical systems

(76) Inventors: Jennifer Shih, Corvallis, OR (US); Valerie J. Marty, Corvallis, OR (US); James Przybyia, Philomath, OR (US); Arthur Piehl, Corvallis, OR (US); John L. Williams, Philomath, OR (US); Christopher Leonard, Philomath, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/703,762

(22) Filed: Nov. 7, 2003

(51) Int. Cl. H01L 21/00

(52) U.S. Cl. 438/48; 438/51

(57) ABSTRACT

A method of sealing a micro-electromechanical system (MEMS) includes successively depositing and etching a sealing material to seal an opening in the MEMS.

### BACKGROUND

Micro-electromechanical systems (MEMS) is a technology that combines processors and circuits with tiny mechanical devices such as pressure and temperature sensors, vibration sensors, valves, gears, mirrors, and actuators embedded in semiconductor chips. Typical MEMS combine sensing, processing and/or actuating functions to alter the way that the physical world is perceived and controlled. They typically combine two or more electrical, mechanical, biological, magnetic, optical or chemical properties on a single microchip.

Integrated circuit and MEMS packaging can be very expensive. As used herein, “packaging” refers to any post-fabrication processing to prepare a MEMS for incorporation into a larger system or to actually incorporate the MEMS into a larger system.

Typically, MEMS are fabricated at one facility and then moved to another location or another facility for packaging. Packaging MEM systems is costly and complex and is currently not done in fabrication facilities. This two-location process, however, dramatically increases the expense of the product.

### BRIEF DESCRIPTION OF THE DRAWINGS

The accompanying drawings illustrate various embodiments of the present invention and are a part of the specification. The illustrated embodiments are merely examples of the present invention and do not limit the scope of the invention.

FIG. 1 is a cross-sectional view of a MEMS unit under production according to a one embodiment of the principles described in this specification.

FIG. 2 is a cross-sectional view of the MEMS unit of FIG. 1 at a later point in the production cycle, when the interior has been sealed.

FIG. 3 is a cross-sectional view showing more of the MEMS unit of FIG. 2.

FIG. 4 is a flowchart illustrating a method of sealing a MEMS unit according to one embodiment.

FIG. 5 is a flowchart illustrating a method of sealing a MEMS unit according to another embodiment.

FIG. 6 is a flowchart illustrating a method of sealing a MEMS unit according to still another embodiment.

Throughout the drawings, identical reference numbers designate similar, but not necessarily identical, elements.

### DETAILED DESCRIPTION

A recent trend has been to try developing methods for packaging MEM systems at the same time and location that the MEM systems are fabricated. This will be referred to as “in-fab packaging.” Packaging that is done within the fabrication facility can drastically decrease the end cost of the product. Moreover, with in-fab packaging, the MEM system can be environmentally sealed, protected from particles, contamination, and moisture in a controlled environment.

The present specification describes a process of packaging or sealing a MEM system by depositing material to seal voids in the MEMS structure. In one embodiment, a film is deposited on top of a completed MEMS structure. The purpose of this film is to reduce the size of the opening that was used to isotropically etch out the cavity in which the MEM system is formed. The film is then anisotropically etched to remove excess material on the top of the structure, to control thickness, and to remove material that was deposited at the bottom of the vertical opening. A subsequent film layer is then deposited to completely fill the opening and passivate the entire device. The deposited film may be, for example, a dielectric or metal material.

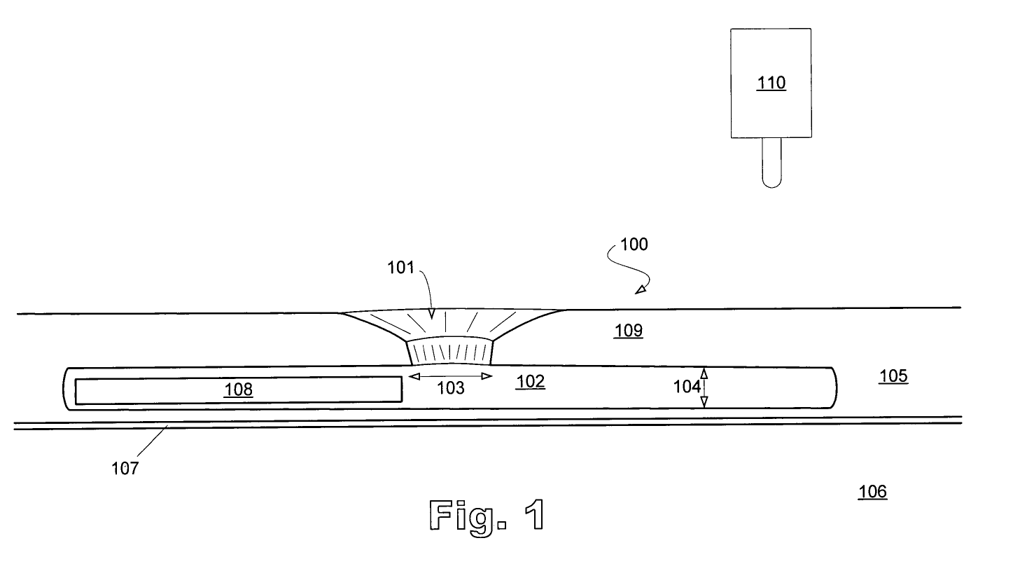

Referring now to FIG. 1, a MEM system is typically formed in a cavity (102) that is formed in a material (105) deposited on a substrate (106). This cavity (102), also referred to as a, chamber, air gap or lateral void, houses the MEM system and accommodates the movement of the mechanical portions of the MEM system (108). The substrate (106) may be, for example, a silicon substrate.

A layer of materials (107) formed on the substrate (106) under the cavity (102) may include, for example, an oxide layer (e.g., 200 Å) over an aluminum copper layer (e.g., 1,200 Å) over a titanium nitride layer (e.g., 500 Å) over a thermal oxide layer (e.g., 1,000 Å).

To create the cavity (102) that accommodates the MEM system and any movement of system components, the material (105) is isotropically etched and then removed to form the cavity (102). The material (105) may be, for example, amorphous silicon. The isotropic etchant removes the sacrificial material (105) through a release hole or opening (101) in the top film (109). The top film (109) may be, for example, an oxide of approximately 10,000 Å in depth.

The MEM system can then be formed in the cavity (102), after which the unit (100) is ready for packaging. As part of the packaging process, the opening (101) is sealed. Sealing the opening (101) is performed to protect the potentially fragile MEM system from particles, moisture and other sources of contamination. The opening (101) that needs to be sealed may have a width (103) of two microns, for example. By comparison, the cavity (102) may have a height (104) of one micron, for example.

As described herein, sealing the opening (101) can be performed as part of an in-fab packaging process in which a film is deposited on top of the completed MEMS unit (100). The purpose of this first deposited film is to partially fill or reduce the size of the opening (101) that was used for the isotropic etch.

The deposited film is then anisotropically etched to remove excess material on the top film (109), to control thickness, and to remove material that was deposited at the bottom of the opening (101) in the cavity (102). A subsequent film layer is then deposited to completely fill the opening (101) and to passivate the entire device (100). The deposited film may include, for example, a dielectric or metal material. As shown in FIG. 1, this deposition-etch-deposition process can be performed by, for example, a deposition and etching system (110) which will be described in more detail below.

The two depositions described in this example will adequately fill a one-micron opening (101), thereby sealing the cavity (102). However, the deposition-etch-deposition process can be repeated subsequent times to fill a larger opening. Alternatively, if the opening (101) is smaller, a single deposition without any subsequent etching may be sufficient to seal the cavity (102). These depositions and etches can all be done with minimal impact to the MEM system in the cavity (102).

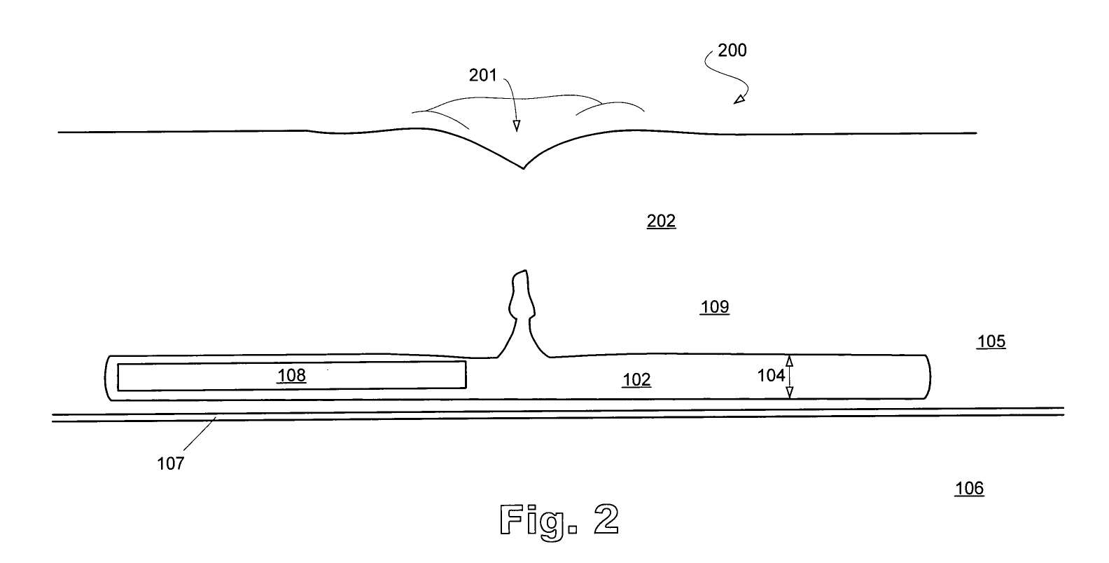

FIG. 2 illustrates the structure of FIG. 1 following the sealing of the opening (101). As indicated above, the opening (101) is sealed by, for example, the deposition of a layer of dielectric (e.g., an oxide), etching of that deposited layer and the deposition of a second layer of dielectric to completely seal the opening (101). As shown in FIG. 2, this process results in a seal (201) that has been formed in what was formerly the opening (101, FIG. 1). Thus, the structure (200) is now a sealed MEMS unit.

The top layer (202) has increased in size due to second deposition of sealing material to sealing the opening. For example, the new top layer (202) may have another 10,000 Å of oxide above the previous top layer (109, FIG. 1) that was present prior to the sealing of the opening (101). A depression in the top layer (202) may indicate where the opening (101) existed previously.

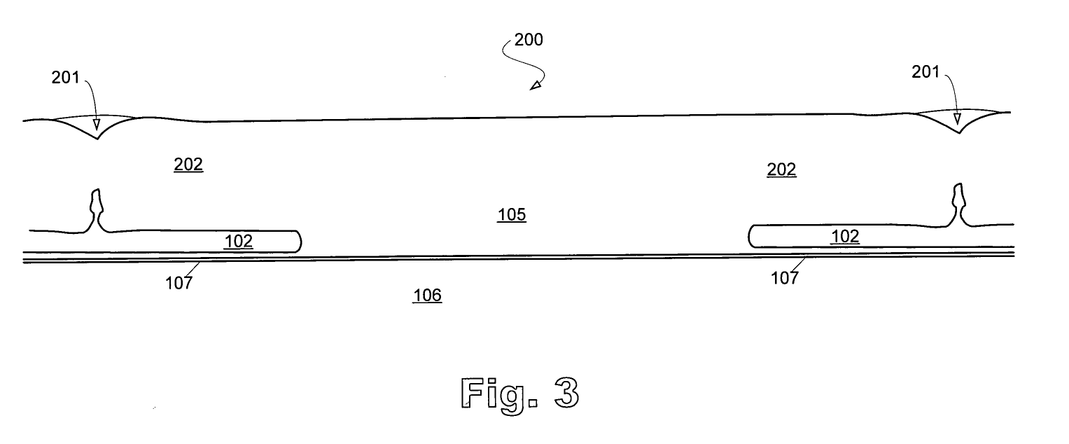

FIG. 3 illustrates that a number of cavities (102) and MEM systems may be formed simultaneously on a single substrate (106). A single sealing operation as described herein can be used to seal all the openings to each of the cavities (102) on the substrate, i.e., the deposition of a layer of dielectric (e.g., an oxide), etching of that deposited layer and the deposition of a second layer of dielectric to completely seal the openings.

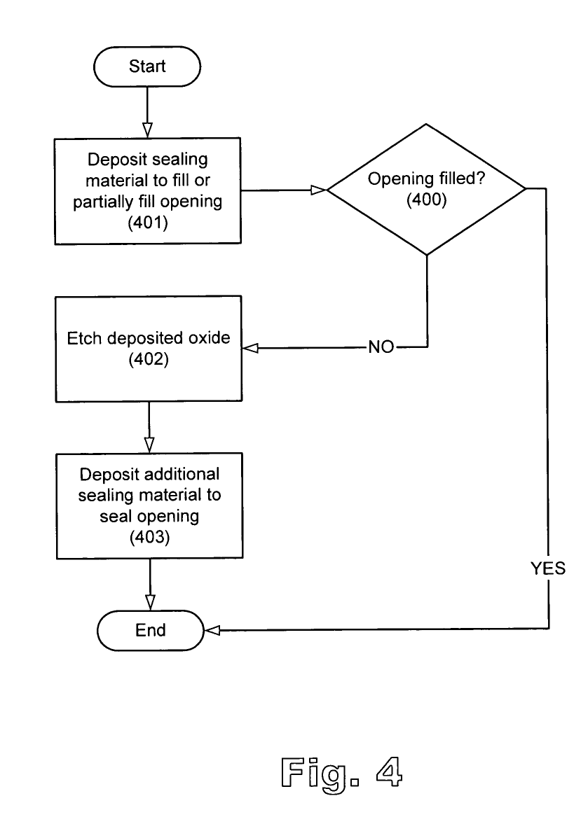

FIG. 4 is a flowchart illustrating a method of sealing a MEM system. As shown in FIG. 4, and as described herein, the process begins with the deposition (step 401) of a sealing material layer to fill or partially fill an opening that extends from a surface of the MEMS structure into a cavity or void where the MEM system is formed. As indicated above, the material deposited may be a dielectric, for example, an oxide, or a metal material.

Depending on the size of the opening being filled, this first deposition (step 401) may completely seal the opening and the process ends (determination 400). Assuming, however, that the first deposition only partially fills the opening (determination 400), following the deposition of this first layer of sealing material, the structure is etched (step 402). For example, the structure is anisotropically etched to remove excess dielectric from the top of the structure, to control thickness, and to remove dielectric that was deposited at the bottom of the opening in the MEMS cavity.

Lastly, another layer of sealing material is deposited (step 403) to completely fill the opening into the MEMS cavity. In this way, the MEM system is hermetically sealed.

A lamp-heated oxide Chemical Vapor Deposition (CVD) chamber with a bubbler-style vapor delivery of tetraethylorthosilicate (TEOS) may be used. TEOS is the precursor used to form the oxide. Both depositions, first and second, can use the same Plasma Enhanced CVD (PECVD) process parameters, varied only by the time given to obtain the desired deposition thickness.

In a particular example with an opening (101, FIG. 1) having a width of 1000 nm, the initial deposition provides 400 nm TEOS oxide. The subsequent etch time is 40 seconds. However, the etch could be specified by an endpoint instead of a fixed time, in which case the end of etching could be triggered by a significant drop in the emission signal when the oxide clears. The final deposition provides 1000 nm of TEOS oxide and makes the final seal.

In this example, top down Scanning Electron Microscopy (SEM) images of a test wafer illustrated a decreased opening diameter of less than 650 nm after the first deposition. Cross sectional SEM images confirmed that the sidewalls of the opening were covered with oxide. Additionally, 250 nm of oxide were initially deposited on the silicon at the bottom of the release hole. With an etch rate of 625 nm/min, 40 seconds was sufficient time to remove all of the oxide from the surface of the oxynitride and the bottom of the cavity, with an ample oxide thickness remaining on the sidewalls of the opening. Over-etching may also result in removal of some oxynitride as well as silicon at the bottom of the opening, which may prove to be beneficial. The diameter of the opening after the etching increased to 725 nm. The final deposition then sealed the opening. Cross sections of wafers after the final deposition confirm net increase of less than 250 nm remaining on the silicon inside the cavity (102, FIG. 1).

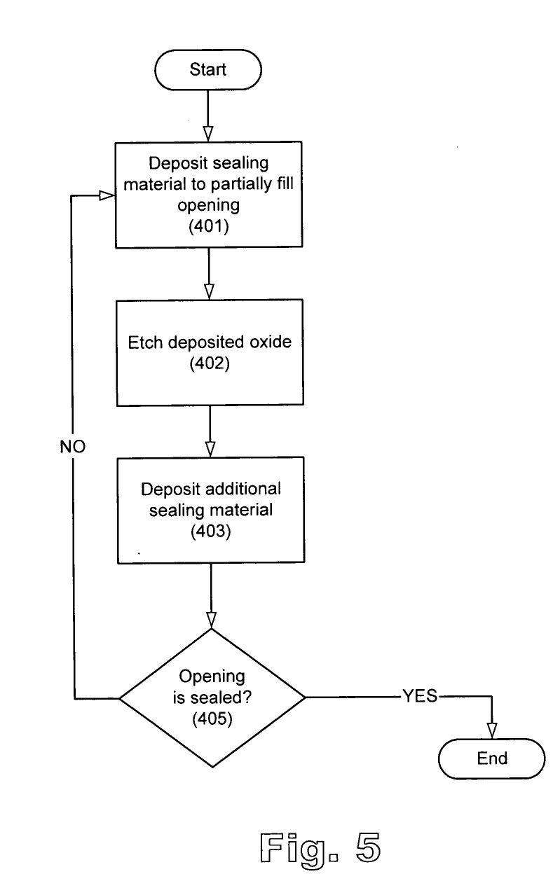

FIG. 5 is a flowchart illustrating a similar method used for sealing MEM systems when the opening into the MEMS cavity is too large to be filled with only the two depositions described above in connection with FIG. 4. As shown in FIG. 5, after the second deposition of sealing material (step 403), the opening into the MEMS cavity or other openings in the MEMS structure may not yet be filled (determination 405).

If the opening is not sealed, the steps of depositing a sealing material (step 401), etching that material (step 402) and depositing another layer of material (step 403) can be repeated until the opening is sealed (determination 405). When the opening is sealed, the process ends.

By tuning the deposition thickness and incorporating multiple deposition-etch-deposition cycles, it is possible to seal any sized opening or release hole with only the slightest additional film remaining on the bottom of the cavity (102, FIG. 1). The over-etching can also be tuned to achieve the desired results.

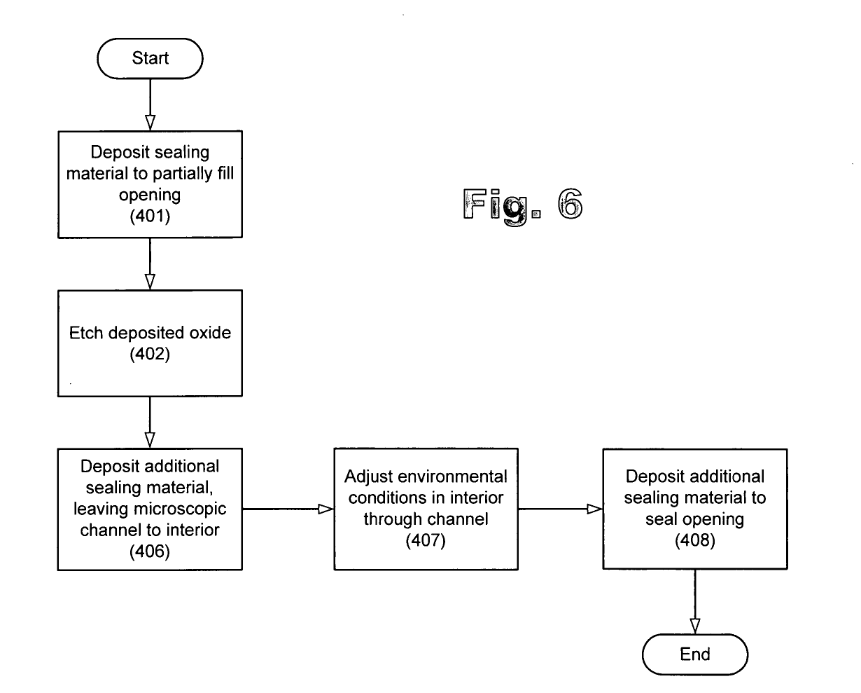

FIG. 6 is a flowchart illustrating another method of sealing a MEM system while controlling the environmental conditions inside the sealed MEMS structure. As shown in FIG. 6, the process begins with the deposition (step 401) of a sealing material layer to partially fill the opening that extends from the surface of the MEMS structure into the cavity or void where the MEM system is formed. As before, the material deposited is a dielectric, for example, an oxide.

Following the deposition of this first layer of sealing material, the structure is etched (step 402). For example, the structure is anisotropically etched to remove excess dielectric from the top of the structure, to control thickness, and to remove dielectric that was deposited at the bottom of the opening in the MEMS cavity.

Then, another layer of sealing material is deposited (step 406). However, this deposition does not completely fill the opening into the MEMS cavity, but rather leaves a very small channel, referred to as a pinhole, leading into the MEMS cavity.

Before the opening is completely sealed, the environmental conditions inside the MEMS structure, e.g., humidity, pressure, etc., are adjusted through the pinhole (step 407). The pinhole can be used to make any environmental adjustment desired including, for example, providing a desiccant in the sealed device. When the environmental conditions inside the MEMS structure have been adjusted as desired, a final deposition of sealing material is made to seal the channel (step 408).

By optimizing deposition/etch cycles to reduce the opening to a pinhole, various process conditions and film types can then be applied to season the chamber and finally seal the pinhole. In this way, the MEM system is hermetically sealed with the desired environmental conditions being established inside the MEMS structure. Alternatively, the seal provided can be non-hermetic depending on the desired characteristics of the internal MEMS environment.

It should be noted that depending on the initial size of the opening being sealed, in some cases, there may be two or more deposition-etch-deposition cycles to narrow the opening down to the desired pinhole. Any number of deposition-etch-deposition cycles can be performed as suits a particular application.

Depending on the pressure desired in the MEMS structure, a film that could be used to achieve 60 to 100 Torr pressure would be ozone-tetraethylorthosilicate (TEOS)-based oxide or Sub-Atmospheric (pressure) Chemical Vapor Deposited (SACVD) TEOS-based oxide. A brief deposition of such material will fill the pinhole, then a subsequent deposition can be made to cover the high pressure TEOS-based film with something more robust and less prone to moisture-absorption.

There are various possibilities regarding film composition. Silane-based oxides have greater sidewall coverage than TEOS oxide and may perform better as the initially deposited film. Though PECVD TEOS oxide can be deposited on the order of a Torr, pressures can be increased to near atmospheric levels using ozone TEOS-based oxides. Another example would be the use of nitride films if a better moisture barrier is needed. The in-fab packaging methodology described herein is flexible to the requirements of many MEMS applications.

If it is critical to maintain certain optical properties of the cavity (102), and the MEM system formed therein, oxide films having a low index of refraction (i.e., a low n value) can be used, for example, oxide films having an index of refraction of 1.6 or less can be used. However, other dielectrics can be used for MEM systems that are not optically sensitive.

As indicated above, MEM systems are historically difficult and expensive to package. The advantages of this in-fab packaging method include controlling the MEMS environment, for example, humidity and pressure. Moreover, in-fab packaging makes the MEM system less sensitive to subsequent packaging because of the hermetic seal provided by closing the opening (101, FIG. 1).

In-fab packaging is also simpler than out-of-fab packaging because in-fab packaging combines passivation with packaging of the device. In addition to passivation, in-fab packaging can also be used to deposit a covering layer that can cover areas of the device that may have a poor appearance or undesirable optical outputs. In cases where the MEM system includes sensitive optics or moving parts that may be damaged by transportation, in-fab packaging makes it possible to package and passivate the device despite the device's low tolerance for movement.

A particular application of the principles described herein would be to provide simple and cost effective packaging for a Digital Light Device (DLD) MEMS. In the DLD manufacturing process, a chamber (e.g., cavity (102)) is created to allow for electromechanical movement of a pixel plate suspended in the chamber by flexures above a bottom capacitor plate (BCP).

As with other MEM systems, openings or release holes through the pixel plate are needed to remove the sacrificial material and create the chamber. The openings are then hermetically sealed, but need to be sealed without inhibiting the functional motion of the corresponding pixel plate. Additionally, an optically critical MEM system such as DLD needs to be sealed to prevent air intrusion. Air negatively impacts the performance by reducing the frequency response of the capacitor plate. As indicated above, in-fab packaging or “in-situ encapsulation” permits controlled tuning of the MEMS internal environment, including moisture content and pressure.

The challenge of sealing the chamber for a DLD is that the 1000 nm opening is relatively large and must be sealed without mechanically connecting the ceiling of the chamber (i.e., the pixel plate) to the floor (the BCP). Such bridging would obstruct the device operation.

In a DLD, the desired depth of the distance between the pixel plate and BCP is approximately 500 nm. The diameter of the opening is twice this distance. For such conditions, where the bridging distance is substantially less than the gap dimension, standard plasma enhanced chemical vapor deposition (PECVD) is inadequate to seal the release hole.

As described, the in-fab packaging methodology described herein incorporates a deposition-etch-deposition sequence to seal the chamber without bridging. The purpose of the initial deposition and etch is to reduce the diameter of the opening to be sealed without leaving any substantial deposition on the surface of the pixel plate or the exposed bottom capacitor plate. The second deposition seals the reduced opening and passivates the device.

The preceding description has been presented only to illustrate and describe embodiments of invention. It is not intended to be exhaustive or to limit the invention to any precise form disclosed. Many modifications and variations are possible in light of the above teaching. It is intended that the scope of the invention be defined by the following claims.

1. A method of sealing a micro-electromechanical system (MEMS), said method comprising successively depositing and etching a sealing material to seal an opening in said MEMS.

2. The method of claim 1, wherein said successively depositing and etching a sealing material comprises:
depositing a first layer of sealing material to partially close said opening;
etching said first layer of sealing material; and
depositing a second layer of sealing material to seal said opening.

3. The method of claim 1, wherein said etching comprises anisotropic etching.

4. The method of claim 1, wherein said depositing comprises chemical vapor deposition.

5. The method of claim 1, wherein depositing a sealing material comprises depositing a dielectric material.

6. The method of claim 5, wherein depositing a dielectric material comprises depositing an oxide.

7. The method of claim 1, wherein said successively depositing and etching said sealing material comprises two or more cycles, each cycle comprising depositing said sealing material, etching said sealing material and again depositing said sealing material.

8. The method of claim 1, wherein said successively depositing and etching a sealing material comprises:
successively depositing and etching said sealing material to narrow said opening;
adjusting conditions in a MEMS cavity through the narrowed opening; and
depositing additional sealing material to seal said narrowed opening.

9. The method of claim 8, wherein said adjusting conditions comprises adjusting pressure.

10. The method of claim 8, wherein said adjusting conditions comprises adjusting humidity.

11. The method of claim 1, further comprising passivating said MEMS with said sealing material.

12. The method of claim 11, further comprising forming a covering layer over said MEMS with said sealing material.

13. A method of forming a micro-electromechanical system (MEMS), said method comprising:
forming a cavity in a material;
forming components of said MEMS in said cavity; and
successively depositing and etching a sealing material to seal an opening into said cavity.

14. The method of claim 13, wherein said forming a cavity comprises isotropic etching of said material through said opening.

15. The method of claim 13, wherein said successively depositing and etching a sealing material comprises:
depositing a first layer of sealing material to partially close said opening;
etching said first layer of sealing material; and
depositing a second layer of sealing material to seal said opening.

16. The method of claim 13, wherein said etching comprises anisotropic etching.

17. The method of claim 13, wherein said depositing comprises chemical vapor deposition.

18. The method of claim 13, wherein depositing a sealing material comprises depositing a dielectric material.

19. The method of claim 18, wherein depositing a dielectric material comprises depositing an oxide.

20. The method of claim 13, wherein said successively depositing and etching said sealing material comprises two or more cycles, each cycle comprising depositing said sealing material, etching said sealing material and again depositing said sealing material.

21. The method of claim 13, wherein said successively depositing and etching a sealing material comprises:
successively depositing and etching said sealing material to narrow said opening;
adjusting conditions in a MEMS cavity through the narrowed opening; and
depositing additional sealing material to seal said narrowed opening.

22. The method of claim 20, wherein said adjusting conditions comprises adjusting pressure.

23. The method of claim 20, wherein said adjusting conditions comprises adjusting humidity.

24. The method of claim 13, further comprising passivating said MEMS with said sealing material.

25. The method of claim 13, further comprising hermetically sealing said opening.

26. A method of in-fab packaging of a micro-electromechanical system (MEMS), said method comprising:
fabricating said MEMS at a fabrication facility; and,
at said fabrication facility, successively depositing and etching a sealing material to seal an opening in said MEMS.

27. The method of claim 26, wherein said successively depositing and etching a sealing material comprises:
depositing a first layer of sealing material to partially close said opening;
etching said first layer of sealing material; and
depositing a second layer of sealing material to seal said opening.

28. The method of claim 26, wherein said etching comprises anisotropic etching.

29. The method of claim 26, wherein said depositing comprises chemical vapor deposition.

30. The method of claim 26, wherein depositing a sealing material comprises depositing a dielectric material.

31. The method of claim 30, wherein depositing a dielectric material comprises depositing an oxide.

32. The method of claim 26, wherein said successively depositing and etching said sealing material comprises two or more cycles, each cycle comprising depositing said sealing material, etching said sealing material and again depositing said sealing material.

33. The method of claim 26, wherein said successively depositing and etching a sealing material comprises:
successively depositing and etching said sealing material to narrow said opening;
adjusting conditions in a MEMS cavity through the narrowed opening; and
depositing additional sealing material to seal said narrowed opening.

34. The method of claim 33, wherein said adjusting conditions comprises adjusting pressure.

35. The method of claim 33, wherein said adjusting conditions comprises adjusting humidity.

36. The method of claim 26, further comprising passivating said MEMS with said sealing material.

37. A method of forming a micro-electromechanical system (MEMS) comprising a Digital Light Device (DLD), said method comprising:
forming a cavity in a material;
forming a pixel plate and a bottom capacitor plate of said DLD in said cavity; and
successively depositing and etching a sealing material to seal an opening into said cavity.

38. The method of claim 37, wherein said forming a cavity comprises isotropic etching of said material through said opening.

39. The method of claim 37, wherein said successively depositing and etching a sealing material comprises:
depositing a first layer of sealing material to partially close said opening;
etching said first layer of sealing material; and
depositing a second layer of sealing material to seal said opening.

40. The method of claim 39, wherein said etching comprises anisotropic etching.

41. The method of claim 39, wherein said depositing comprises chemical vapor deposition.

42. The method of claim 39, wherein depositing a sealing material comprises depositing a dielectric material.

43. The method of claim 42, wherein depositing a dielectric material comprises depositing an oxide.

44. The method of claim 39, wherein said successively depositing and etching said sealing material comprises two or more cycles, each cycle comprising depositing said sealing material, etching said sealing material and again depositing said sealing material.

45. The method of claim 39, wherein said successively depositing and etching a sealing material comprises:
successively depositing and etching said sealing material to narrow said opening;
adjusting conditions in a MEMS cavity through the narrowed opening; and
depositing additional sealing material to seal said narrowed opening.

46. The method of claim 45, wherein said adjusting conditions comprises adjusting pressure.

47. The method of claim 45, wherein said adjusting conditions comprises adjusting humidity.

48. The method of claim 39, further comprising passivating said MEMS with said sealing material.

49. A sealed micro-electromechanical system (MEMS) comprising components sealed in a cavity formed on a substrate, said system being formed by successively depositing and etching a sealing material to seal an opening into said cavity.

50. A sealed micro-electromechanical system (MEMS), said system comprising:
components sealed in a cavity formed on a substrate; and
a deposited dielectric layer sealing an opening into said cavity.

51. The system of claim 50, wherein said dielectric comprises an oxide.

52. The system of claim 50, wherein said components comprise a pixel plate and bottom capacitor plate of a digital light device.

53. A system for sealing a micro-electromechanical system (MEMS), said system comprising:
means for forming a cavity on a substrate containing components of said MEMS; and
means for successively depositing and etching a sealing material to seal an opening into said cavity.

54. The system of claim 53, wherein said means for successively depositing and etching a sealing material comprise:
means for depositing a first layer of sealing material to partially close said opening;
means for etching said first layer of sealing material; and
means for depositing a second layer of sealing material to seal said opening.

55. The system of claim 53, wherein said sealing material comprises a dielectric material.

56. The system of claim 55, wherein said dielectric material comprises an oxide.

57. A method of sealing a micro-electromechanical system (MEMS), said method comprising depositing a layer of sealing material to seal an opening that extends through a deposited material into a cavity in said deposited material containing said MEMS.

58. The method of claim 57, wherein said depositing said layer further comprises successively depositing and etching layers of said sealing material.

59. The method of claim 58, further comprising:
depositing a first layer of sealing material to partially close said opening;
etching said first layer of sealing material; and
depositing a second layer of sealing material to seal said opening.

60. The method of claim 58, wherein said etching comprises anisotropic etching.

61. The method of claim 57, wherein said depositing comprises chemical vapor deposition.

62. The method of claim 57, wherein depositing a sealing material comprises depositing a dielectric material.

63. The method of claim 62, wherein depositing a dielectric material comprises depositing an oxide.

64. The method of claim 57, wherein depositing a sealing material comprises depositing a metal material.
